(19) United States
(12) Patent Application Publication
(10) Pub. No.: US 2021/0384038 A1
(43) Pub. Date: Dec. 9, 2021

(54) SUBSTRATE PROCESSING METHOD AND SUBSTRATE PROCESSING APPARATUS

(71) Applicant: Tokyo Electron Limited, Tokyo (JP)

(72) Inventor: Shuichiro UDA, Miyagi (JP)

(21) Appl. No.: 17/303,558

(22) Filed: Jun. 2, 2021

(30) Foreign Application Priority Data
Jun. 5, 2020 (JP) 2020-098837

(51) Int. Cl. H01L 21/311; H01J 37/32; H01L 21/3065

(52) U.S. Cl. CPC H01L 21/31116; H01J 37/32449; H01J 2237/334; H01L 21/3065; H01L 21/31144

(57) ABSTRACT

A substrate processing method of etching a substrate that has a film to be etched and a mask film covering the film to be etched, wherein the mask film has an opening to expose part of the film to be etched, includes A) supplying a first gas containing electron receptors to the film to be etched, through the opening; B) supplying plasma of a second gas containing oxygen to the film to be etched; and C) applying plasma etching to the film to be etched.

### CROSS-REFERENCE TO RELATED APPLICATIONS

The present application is based upon and claims the benefit of priority to Japanese Patent Application No. 2020-098837 filed on Jun. 5, 2020, the entire contents of which are hereby incorporated by reference.

### TECHNICAL FIELD

The present disclosure relates to a substrate processing method and a substrate processing apparatus.

### BACKGROUND

Japanese Laid-Open Patent Application No. 2010-109373 shows that plasma of an open gas comprising COS is generated in an opening of a functional organic mask layer. Also, Japanese Patent Publication No. 5642001 shows that when etching an organic film on a substrate to be processed by using an inorganic film, a negative DC voltage is applied to an upper electrode during the etching, to form a protection film constituted with a silicon-containing material for the upper electrode, on the side walls of the etched portion.

### SUMMARY

A substrate processing method according to one aspect in the present disclosure is a substrate processing method of etching a substrate that has a film to be etched and a mask film covering the film to be etched, wherein the mask film has an opening to expose part of the film to be etched; the substrate processing method includes A) supplying a first gas containing electron receptors to the film to be etched, through the opening; B) supplying plasma of a second gas containing oxygen to the film to be etched; and C) applying plasma etching to the film to be etched.

### BRIEF DESCRIPTION OF THE DRAWINGS

FIG. 1 is a flow chart of a substrate processing method according to a first embodiment;

FIG. 2 is a schematic diagram of a substrate before etching;

FIG. 3 is a schematic diagram of the substrate in which a recess is formed on the surface in FIG. 2;

FIG. 4 is a schematic diagram of the substrate to which a first gas containing electron receptors is supplied in FIG. 3;

FIG. 5 is a schematic diagram of the substrate to which plasma of a second gas containing oxygen is supplied in FIG. 4, to etch the substrate;

FIG. 6 is a schematic diagram of the substrate to which the first gas containing electron receptors is further supplied in FIG. 5;

FIG. 7 is a schematic diagram of the substrate to which plasma of the second gas is further supplied in FIG. 6, to further etch the substrate;

FIG. 8 is a schematic diagram of the substrate further etched in FIG. 7, to form a through hole;

FIG. 9 is a diagram illustrating a state of oxide of the electron receptors being networked three-dimensionally;

FIG. 10 is a flow chart illustrating a modified example of the substrate processing method according to the first embodiment;

FIG. 11 is a flow chart illustrating an example of a substrate processing method according to a second embodiment;

FIG. 12 is a schematic diagram of the substrate to which plasma of the first gas and the second gas is supplied at the same time in FIG. 3;

FIG. 13 is a schematic diagram of the substrate etched in FIG. 12;

FIG. 14 is a schematic diagram of the substrate to which the plasma of the first gas and the second gas is supplied at the same time in FIG. 13;

FIG. 15 is a schematic diagram of the substrate further etched in FIG. 14;

FIG. 16 is a schematic diagram illustrating an example of a substrate processing apparatus according to an embodiment;

FIG. 17 is an SEM image that captures a cross section of a substrate of Application example 1;

FIG. 18 is an SEM image that captures openings in the substrate in FIG. 17;

FIG. 19 is an SEM image that captures a cross section of a substrate of Application example 2;

FIG. 20 is an SEM image that captures openings in the substrate in FIG. 19;

FIG. 21 is an SEM image that captures a cross section of a substrate of Reference example 1;

FIG. 22 is an SEM image that captures openings in the substrate in FIG. 21;

FIG. 23 is an SEM image that captures a cross section of the substrate of Comparative example 1; and

FIG. 24 is an SEM image that captures openings in the substrate in FIG. 23.

### DETAILED DESCRIPTION

In the following, embodiments in the present disclosure are described with reference to the drawings. Note that throughout the drawings, the same or corresponding reference codes may be assigned to common elements, to omit description.

### <Substrate Processing Method>

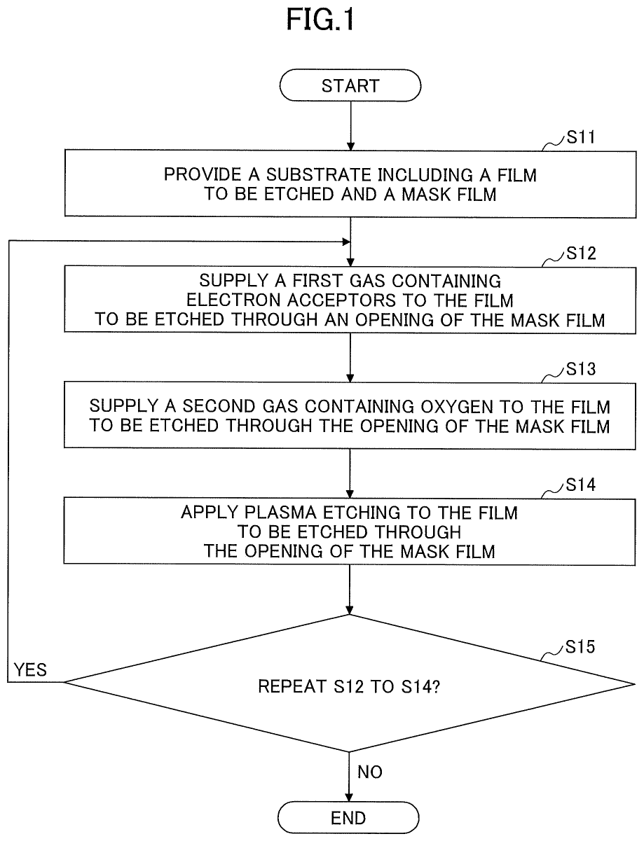

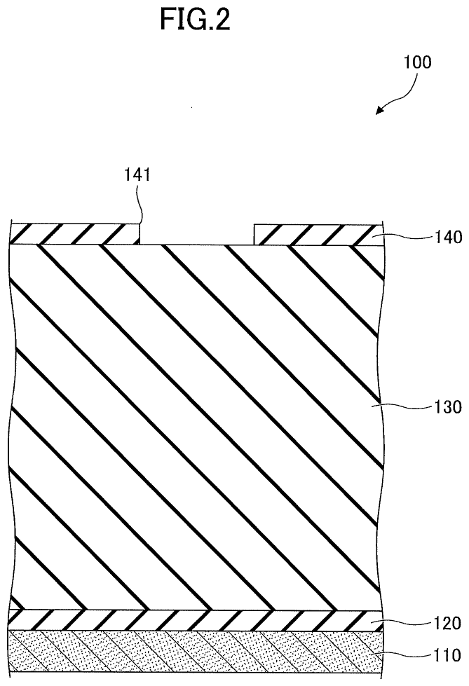

FIG. 1 is a flow chart of a substrate processing method according to a first embodiment. FIGS. 2 to 8 illustrate steps in which a substrate is processed by a substrate processing method according to a first embodiment.

The substrate processing method of the first embodiment is a substrate processing method of etching a substrate that has a film to be etched and a mask film covering the film to be etched, wherein the mask film has an opening to expose part of the film to be etched; the substrate processing method includes A) supplying a first gas containing electron receptors to the film to be etched, through the opening; B) supplying plasma of a second gas containing oxygen to the film to be etched; and C) applying plasma etching to the film to be etched.

In the present disclosure, as illustrated in FIG. 1, Steps S11 to S15 are executed to etch a substrate that has a film to be etched and a mask film covering the film to be etched. In the present specification, etching refers to dry etching that uses a reactive gas, ions, and radicals.

At Step S11, a substrate that has a film to be etched and a mask film is provided (see FIG. 1). In the present specification, the substrate here is a circuit substrate on which films of various materials are layered onto a semiconductor wafer serving as the base (referred to as the wafer, hereafter). In the present disclosure, as illustrated in FIG. 2, a circuit substrate 100 on which a wafer 110, an underlayer film 120, a film to be etched 130, and a mask film 140 are layered in this order is presented. Note that the circuit substrate 100 is an example of a substrate in a substrate processing method in the present disclosure.

In the circuit substrate 100, the wafer 110 is famed of silicon (Si). The underlayer film 120 is an inorganic insulating film that has a structure in which silicon nitride (SiN) and silicon oxide (SiO₂) are layered alternately. Also, the film to be etched 130 is formed of an organic film such as an amorphous carbon film (ACL), and is a target of etching in the present disclosure. The mask film 140 is formed of silicon oxynitride (SiON) or the like, layered on the top surface of the film to be etched 130, and has a function of protecting the film to be etched 130.

Also, in the mask film 140, an opening 141 is formed to expose part of the film to be etched 130. The part of the film to be etched 130 exposed through the opening 141 in the mask film 140 serves as an introductory part through which the film to be etched is etched.

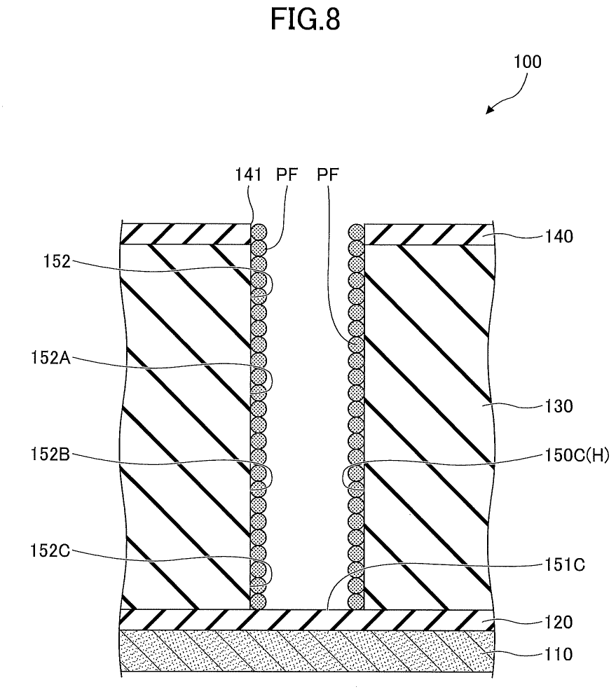

Note that the film to be etched 130 is not limited to an amorphous carbon film (ACL). For example, the film may be formed of an organic material such as a spin-coated film, doped carbon film, BARC, organic low-dielectric constant (organic Low-K) film, or the like. Also, the underlayer film 120 positioned as an underlayer of the film to be etched 130 is not limited to an inorganic insulating film that has a structure in which silicon nitride (SiN) and silicon oxide (SiO₂) are layered alternately. For example, the material may be any one of silicon oxide (SiO₂), silicon nitride (SiN), low dielectric constant (Low-K) film, silicon oxynitride (SiON), silicon carbide (SiC), or any combination of two or more of these. Also, the underlayer film 120 may be an organic film that is different from the film to be etched 130. Note that in the present disclosure, once the film to be etched 130 is etched and a through hole H as illustrated in FIG. 8 is famed as will be described later, the underlayer film 120 is etched where the film to be etched 130 having the through hole H formed serves as the mask film.

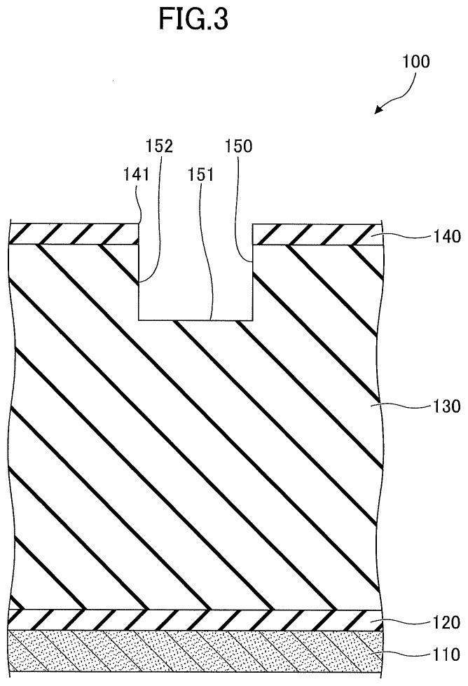

Note that in the present disclosure, as illustrated in FIG. 3, the recess 150 may be formed in advance in part of the film to be etched 130 that is exposed through the opening 141. In this case, a bottom face 151 and side faces 152 are formed inside the recess 150. The recess 150 formed in the film to be etched 130 may be formed by etching according the present embodiment as will be described later, or may be famed by applying other etching or the like.

At Step S12, a first gas containing electron receptors P1 is supplied to the film to be etched 130 through the opening 141 of the mask film 140 (see FIGS. 1, 3, and 4). Here, supplying a gas to the film to be etched 130 through the opening 141 refers to supplying the gas to part of the film to be etched 130 (inside the recess 150 in the present embodiment) that is exposed through the opening 141 of the mask film 140.

Also, an electron receptor refer to a compound that receives electrons from another substance to itself in the case where electron transfer is accompanied. In the present embodiment, the electron receptor is not limited in particular; for example, a Lewis acid compound may be used. The Lewis acid compound here refers to a compound that has a property of accepting electron pairs.

Also, in the case of using a Lewis acid compound as electron receptors, a boron containing compound is more favorable among Lewis acid compounds. Here, a boron containing compound refers to a compound containing boron. A boron containing compound is, for example, a compound expressed by a chemical formula BₙXₘ. Note that in this chemical formula, B is boron, X is an element selected from among halogen such as F, Cl, and Br; H; As; and the like, and n and m are positive integers. Note that as the boron containing compound, among these, boron halide is favorable, and boron trichloride is more favorable.

At Step S12, once the first gas containing electron receptors P1 is supplied to the film to be etched 130 through the opening 141 of the mask film 140, the electron receptors P1 are adsorbed to part of the film to be etched 130 (inside the recess 150) as a precursor to form a protection film as will be described later. The electron receptors P1 also adhere to the mask film 140 including the surroundings of the opening 141.

Note that at Step S12, in the case of supplying the first gas containing the electron receptors P1, it is favorable not to generate plasma. In the present specification, plasma is an ionized state of molecules in each of which a particle (an ion) having a positive charge is dissociated with an electron having a negative charge.

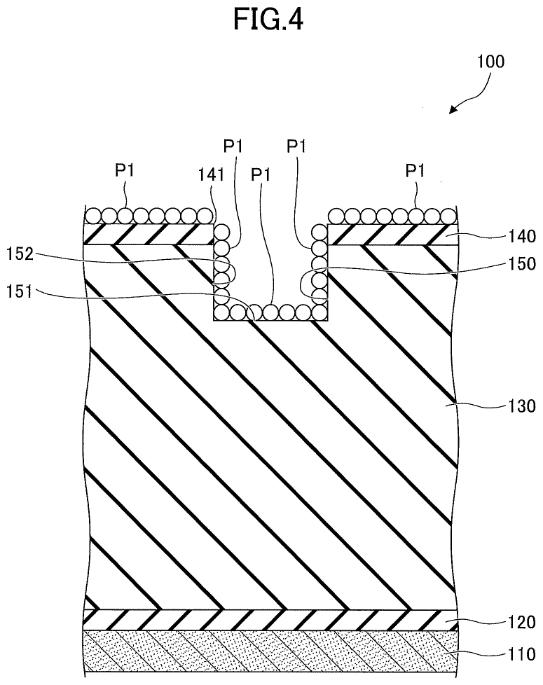

In the present disclosure, the recess 150 is formed in advance in the film to be etched 130 through the opening 141; therefore, the electron receptors P1 are supplied to the inside (the bottom face 151 and the side faces 152) of the recess 150 of the film to be etched 130. The electron receptors P1 (see blank circles in FIG. 4) supplied into the recess 150 of the film to be etched 130 are adsorbed on both the bottom face 151 and the side faces 152 of the recess 150.

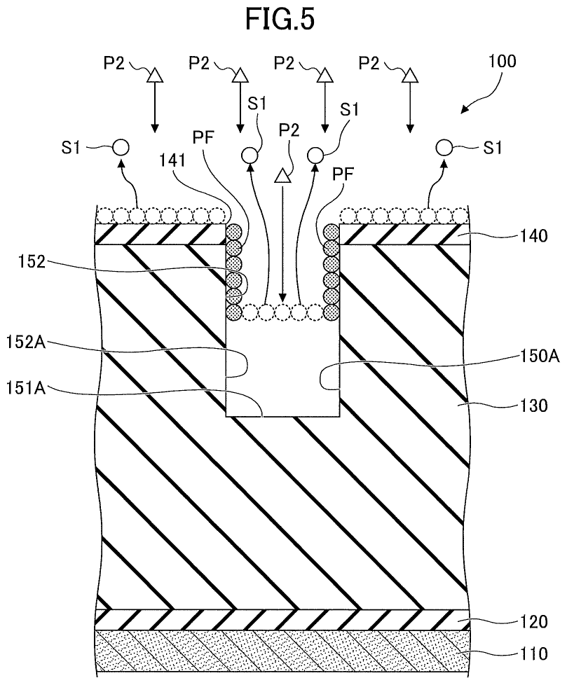

At Step S13, plasma P2 of the second gas containing oxygen is supplied to the film to be etched 130 through the opening 141 of the mask film 140 (FIGS. 1 and 5). In the present disclosure, the plasma P2 of the second gas is plasma of oxygen in which one oxygen molecule is dissociated into two oxygen radicals. Note that supplying plasma refers to having the film to be etched 130 of the circuit substrate 100 come into contact with the plasma.

At Step S13, by supplying the plasma P2 of the second gas containing oxygen to the film to be etched 130 after the first gas has been supplied, among the electron receptors P1 adsorbed on the film to be etched 130, some of the electron receptors P1 react with oxygen radicals in the plasma P2 of the second gas, form oxide PF, and the other electron receptors P1 are removed as sputters S1.

In the present disclosure, the recess 150 is formed in advance in the film to be etched 130 through the opening 141, and the plasma P2 of the second gas (blank triangles in FIG. 5) is supplied to the recess 150 of the film to be etched 130. Then, the electron receptors P1 (dashed-line blank circles in FIG. 5) adsorbed on the bottom face 151 of the recess 150 and the electron receptors P1 adsorbed on the mask film 140 are removed as the sputters S1. Also, the electron receptors P1 (blank circles in FIG. 4) adsorbed on the side faces 152 of the recess 150 react with the plasma P2 of the second gas, to form the oxide PF (hatched circles in FIG. 5) of the electron receptors P1 on the side faces 152 of the recess 150 (see FIG. 5).

Note that in the case where the electron receptors P1 are of a boron containing compound, the reaction of the electron receptors P1 (boron containing compound) with oxygen radicals in the plasma P2 of the second gas can be expressed, for example, by the following reaction formula (1). Note that in the reaction formula (1), B is boron, X is halogen such as chlorine, and n is an integer.

2nBX₃+3nO⇒n(B₂O₃)+3nX₂ (1)

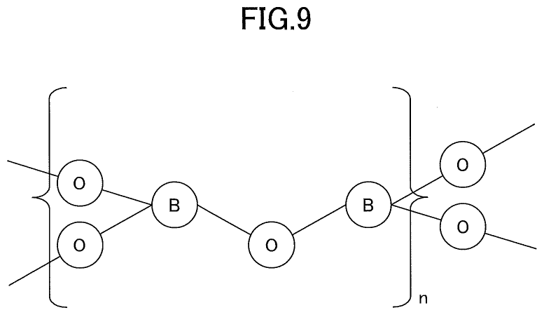

By the reaction expressed by the reaction formula (1), boron trioxide (B₂O₃) is generated as oxide of the electron receptors P1, and the generated oxide of the electron receptors P1 is thought to have a three-dimensionally networked structure (see FIG. 9).

At Step S14, plasma etching is applied to the film to be etched 130 through the opening 141 of the mask film 140 (FIGS. 1 and 5). Here, the plasma etching may be executed with the etching by the plasma P2 of the second gas; alternatively, etching may be executed by generating ions and radicals of a reactive gas, separately from the plasma of the second gas.

In the present disclosure, B) and C) described above are executed at the same time. Specifically, the step of supplying the plasma P2 of the second gas containing oxygen to the film to be etched 130 also serves as the step of applying the plasma etching to the film to be etched 130. In other words, by supplying the plasma P2 of the second gas containing oxygen to the film to be etched 130, the plasma etching is applied to the film to be etched 130 through the opening 141 of the mask film 140 (FIG. 5).

At Step S14, by applying plasma etching to the film to be etched 130, the oxide PF of the electron receptors P1 formed on the film to be etched 130 can protect a portion of the film to be etched 130 at which the oxide PF is famed from the plasma. Also, a portion of the film to be etched 130 (the bottom face 151 of the recess 150) at which the electron receptors P1 has been removed are exposed to the plasma. Accordingly, on the film to be etched 130 of the circuit substrate 100, the portion at which the oxide PF of the electron receptors P1 is formed (the side faces 152 of the recess 150) is not etched, and only the portion at which the oxide PF is not formed (the bottom face 151 of the recess 150) is etched, and a recess 150A (a bottom face 151A and side faces 152A) is newly formed.

In the substrate processing method in the present disclosure, A), B), and C) described above may be repeated. In the present disclosure, in the case where it is determined at Step S15 that Steps S12 to S14 are to be repeated after having applied the plasma etching at Step S14, Steps S12 to S14 are executed again, to repeat the steps of A), B), and C) described above.

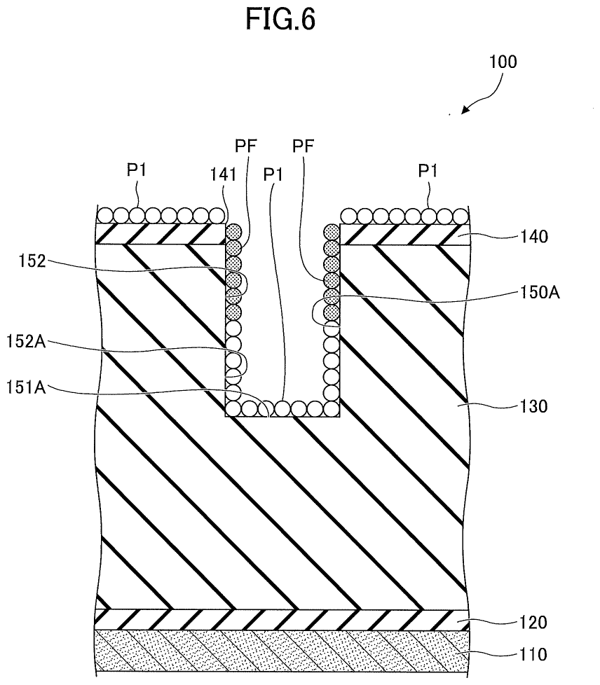

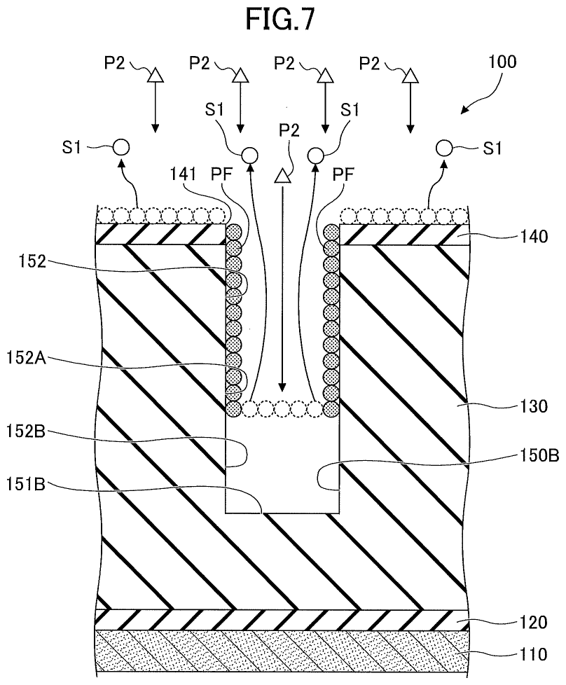

Accordingly, by repeating Steps S12 to S14, the etching advances, the recess 150A is formed in the film to be etched 130 through the opening 141 of the mask film 140, and the electron receptors P1 of the first gas are further adsorbed also on the bottom face 151A and the side faces 152A of the recess 150A (FIG. 6). The electron receptors P1 (dashed-line blank circles in FIG. 7) adsorbed on the bottom face 151A of the recess 150A and the mask film 140 are removed as the sputters S1 by the plasma P2 (blank triangles in FIG. 7) of the second gas supplied subsequently, whereas the electron receptors P1 adsorbed on the side faces 152A of the recess 150B react with the plasma P2 of the second gas while being adsorbed on the side faces 152A, and oxide PF (hatched circles in FIG. 7) of the electron receptors P1 is formed on the side faces 152A of the recess 150 (FIG. 7).

Accordingly, by repeating Steps S12 to S14, recesses 150B and 150C are further formed in the film to be etched 130, the oxide PF of the electron receptors P1 is also formed on the side faces 152B of the recess 150B and the side faces 152C of the recess 150C, and the bottom face 151B of the recess 150B and the bottom face 151C of the recess 150C are etched (FIGS. 7 and 8). By repeating Steps S12 to S14, a through hole H such as the recess 150C is famed (FIG. 8).

In the substrate processing method in the present disclosure, as described above, inside the recess 150 famed in the film to be etched 130, in a state where the side faces 152 (152A, 152B, and 152C) of the recess 150 (recess 150A, 150B, and 150C) are protected by the oxide (protection film) PF of the electron receptors P1, the bottom face 151 (bottom face 151A, 151B, or 151C) is etched. Therefore, according to the substrate processing method in the present disclosure, etching defects such as bowing can be suppressed (see FIGS. 5 to 8).

Also, although the electron receptors P1 of the first gas are also adsorbed on the mask film 140 containing the surroundings of the opening 141, the electron receptors P1 adsorbed on the mask film 140 are removed as the sputters S1 by the plasma of the second gas; therefore, the oxide PF of the electron receptors P1 is not likely to be famed on the mask film 140. Therefore, according to the substrate processing method in the present disclosure, the oxide PF of the electron receptors P1 is not likely to be accumulated around the opening 141 of the mask film 140, the opening 141 of the mask film 140 can be prevented from being blocked (see FIGS. 5 to 8).

Also, in the substrate processing method in the present disclosure, as described above, by using a Lewis acid compound as the electron receptors P1 contained in the first gas, the Lewis acid compound tends to be adsorbed on the film to be etched 130 as a precursor to form a protection film. Also, the Lewis acid compound adsorbed on the film to be etched 130 reacts with oxygen radicals in the plasma of the second gas, to form the oxide PF, and thereby, the protection of the film to be etched 130 from the plasma can be improved at the portion where the oxide PF is formed (see FIGS. 4 to 8).

In the substrate processing method in the present disclosure, as described above, by using a boron containing compound as the electron receptors contained in the first gas, the boron containing compound further tends to be adsorbed on the film to be etched 130 as a precursor to form a protection film. Also, the Lewis acid compound adsorbed on the film to be etched 130 react further with oxygen radicals in the plasma of the second gas, to form the oxide PF. Therefore, the protection of the oxide PF of the film to be etched 130 from the plasma can be further improved at the portion where the oxide PF is formed (see FIGS. 4 to 8).

In the present disclosure, as described above, the recess 150 is formed in advance in the film to be etched 130 through the opening 141; therefore, once plasma for etching including the plasma of the second gas is supplied, inside the recess 150 formed in the film to be etched 130, the bottom face 151 of the recess 150 is etched in a state where the side faces of the recess 150 are protected by the oxide (protection film) PF of the electron receptors P1. Therefore, according to the substrate processing method in the present disclosure, etching defects such as bowing can be suppressed with high precision (see FIGS. 3 to 8).

Also, the electron receptors P1 of the first gas is supplied to the recess 150 formed in the film to be etched 130, and also supplied to the mask film 140, to be adsorbed on the mask film 140 including the surroundings of the opening 141 of the film to be etched 130. However, the electron receptors P1 adsorbed on the mask film 140 is removed as the sputters S1 by the plasma P2 of the second gas; therefore, the oxide PF of the electron receptors P1 is not likely to be formed on the mask film 140. Therefore, according to the substrate processing method in the present disclosure, the oxide PF of the electron receptors P1 is not likely to be accumulated around the opening 141 of the mask film 140, the opening 141 of the mask film 140 can be prevented from being blocked (see FIGS. 3 to 8).

In the substrate processing method in the present disclosure, as described above, by not generating plasma in the case of supplying the first gas containing the electron receptors P1 to the film to be etched 130, the first gas can be prevented from changing to the oxide PF of the electron receptors P1 before supplying the plasma of the second gas. Accordingly, on the film to be etched 130 on which the first gas is absorbed, while protecting a portion at which the oxide PF of the electron receptors P1 is famed by reaction with the plasma P2 of the second gas, only a portion from which the electron receptors P1 are removed as the sputters S1 by the plasma P2 of the second gas, can be etched (see FIGS. 4 to 8).

In the substrate processing method in the present disclosure, as described above, by executing the step of B) and the step of C) at the same time, once the plasma P2 of the second gas containing oxygen is supplied to the film to be etched 130, while forming the oxide PF of the electron receptors P1 on a portion of the film to be etched 130 on which the first gas is adsorbed, only a portion of the film to be etched 130 on which the first gas is not absorbed can be etched (see FIGS. 5 and 7).

Accordingly, when the plasma P2 of the second gas is supplied, the film to be etched 130 can be protected and etched at the same time; therefore, etching defects such as bowing can be suppressed with high precision. Also, by only supplying the plasma P2 of the second gas, the film to be etched 130 can be etched, and hence, the etching process can be executed efficiently (see FIGS. 4 to 8).

In the substrate processing method in the present disclosure, as described above, by repeating the steps of A), B), and C), while protecting part of the film to be etched 130 on which the oxide PF of the electron receptors P1 is formed, etching can be advanced at a portion of the film to be etched 130 on which the oxide PF of the electron receptors P1 is not formed. Also, on part of the newly etched film to be etched 130 (the side faces 152A of the recess 150A, the side faces 152B of the recess 150B, or the side faces 152C of the recess 150C), the oxide PF of the electron receptors P1 is also formed. Therefore, even when the etching is advanced, while protecting the part of the film to be etched 130 (the side faces 152A of the recess 150A, the side faces 152B of the recess 150B, and the side faces 152C of the recess 150C), the film to be etched 130 can be etched (the bottom face 151A of the recess 150A, the bottom face 151B of the recess 150B, or the bottom face 151C of the recess 150C) (see FIGS. 4 to 8).

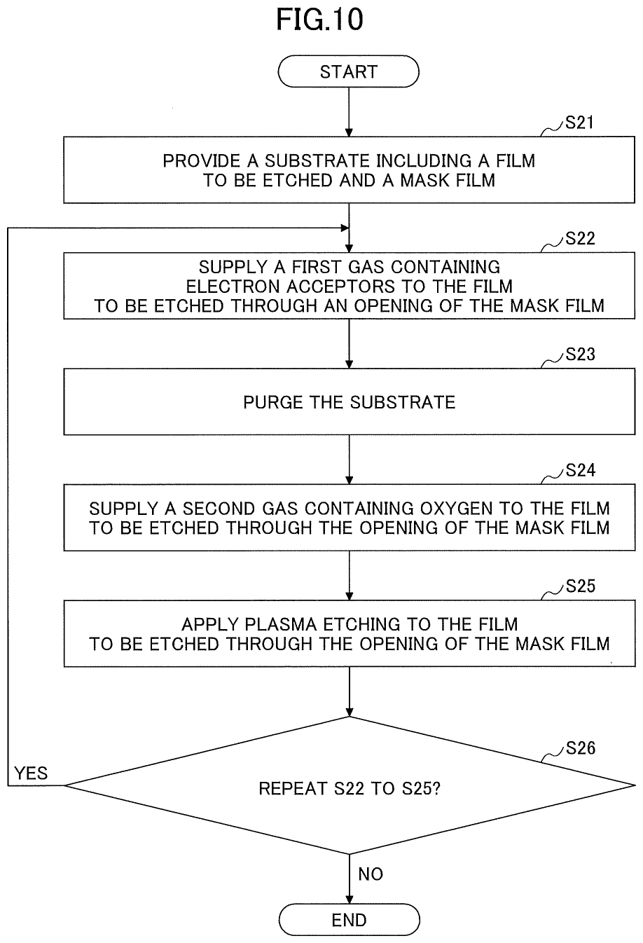

FIG. 10 is a flow chart illustrating a modified example of the substrate processing method according to the first embodiment. Note that in FIG. 10, steps that are common to those in FIG. 1 are assigned reference codes of numbers obtained by adding 10 to the reference codes of numbers assigned in FIG. 1, and the descriptions of those steps are omitted.

The modified example in the present disclosure includes a step of purging the surface of a substrate between A) and B) described above. Specifically, at Step S23, after having supplied the first gas containing electron receptors P1 to the film to be etched 130, before supplying the plasma P2 of the second gas containing oxygen, the circuit substrate 100 is purged (FIG. 10).

In the present specification, purging refers to purifying the surface of a substrate by supplying an inert gas on the surface of the substrate. Although the components of the inert gas used for purging are not limited, a gas that does not undergo a chemical reaction or a gas that is unlikely to undergo a chemical reaction is favorable, a noble gas is more favorable, and argon (Ar) gas is furthermore favorable.

In the substrate processing method in the present disclosure, as described above, before supplying the plasma P2 of the second gas containing oxygen to the film to be etched 130 on which the first gas containing the electron receptors P1 is adsorbed, by purging the surface of the substrate, impurities such as particles accumulated on the film to be etched 130 and the mask film 140, and an excess of the first gas (1st gas not contributing to formation of the oxide PF of the electron receptors P1) can be removed. Accordingly, in the case where the plasma P2 of the second gas is supplied to the surface of the substrate, the oxide PF of the electron receptors P1 can be formed only on a portion at which the film to be etched 130 needs to be protected (the side faces of the recess 150).

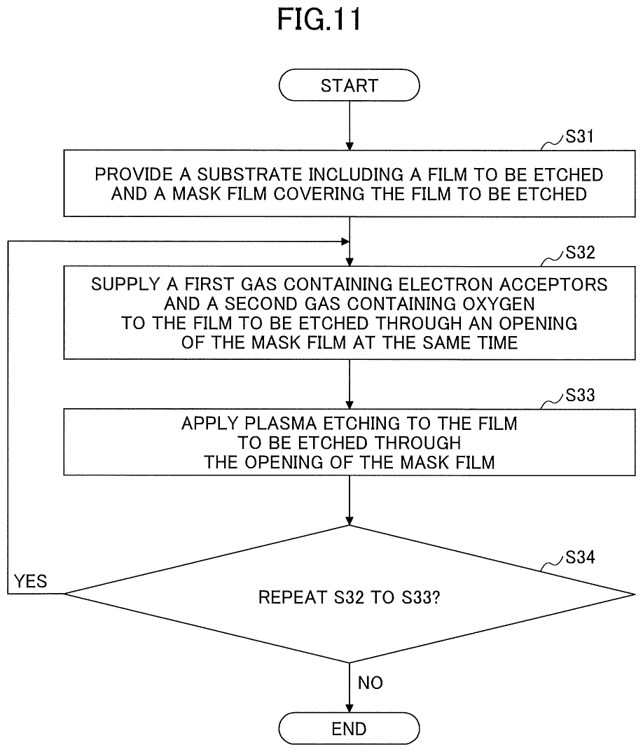

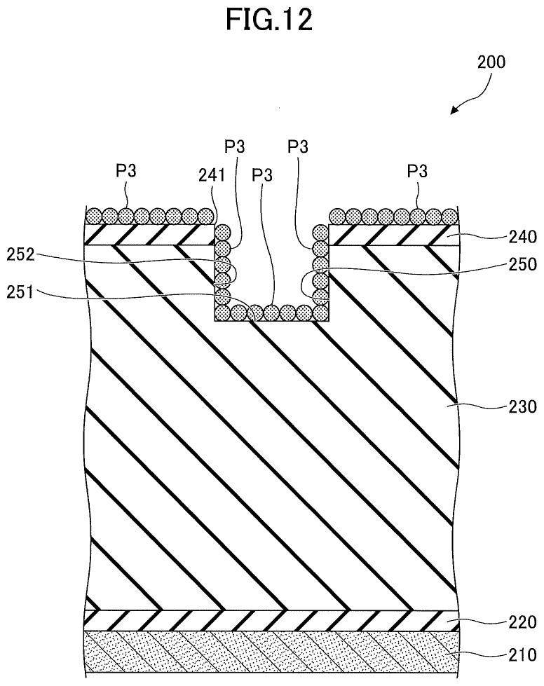

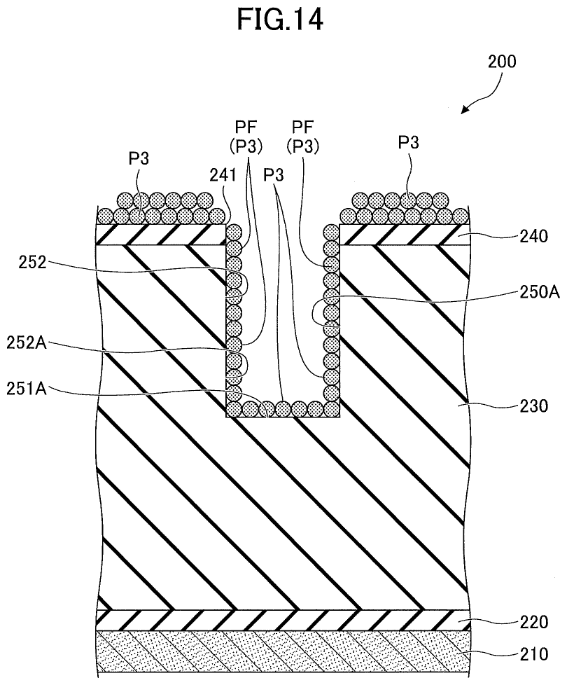

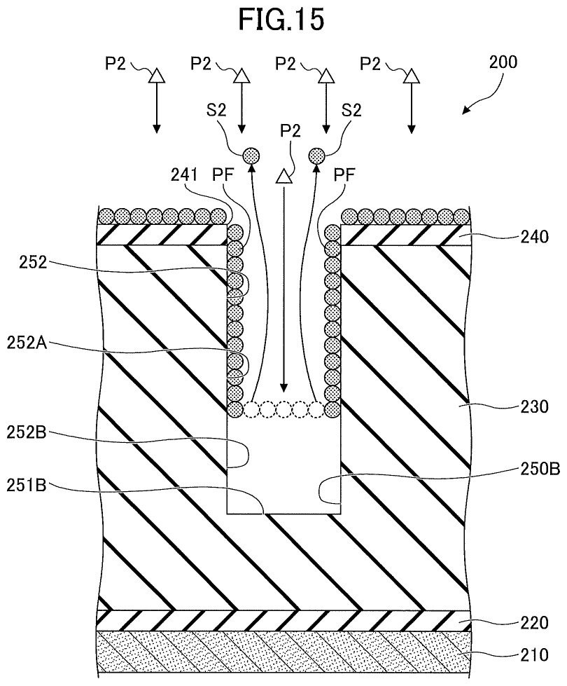

FIG. 11 is a flow chart illustrating an example of a substrate processing method according to a second embodiment. FIGS. 12 to 15 illustrate part of steps in which a substrate is processed in the substrate processing method according to the second embodiment. Note that in FIG. 11, steps that are common to those in FIG. 1 are assigned reference codes of numbers obtained by adding 20 to the reference codes of numbers assigned in FIG. 1, and the descriptions of those steps are omitted. Also, in FIGS. 12 to 15, elements that are common to those in FIGS. 2 to 8 are assigned reference codes of numbers obtained by adding 100 to the reference codes of numbers assigned in FIGS. 2 to 8, and the descriptions of those steps are omitted.

In the second embodiment of the present disclosure, A) and B) described above are executed at the same time. Specifically, at Step S32, the first gas containing the electron receptors P1 and plasma P2 of the second gas containing oxygen is supplied at the same time to the film to be etched 230 through the opening 241 of the mask film 240 (FIGS. 11 and 12). Thereafter, at Step S33, plasma etching is applied to the film to be etched 230 through the opening 241 of the mask film 240.

Note that in the case of supplying the first gas and the plasma of the second gas at the same time, the plasma may be generated by supplying the first gas and second gas separately, or the plasma may also be generated while supplying a mixed gas of the first gas and the second gas.

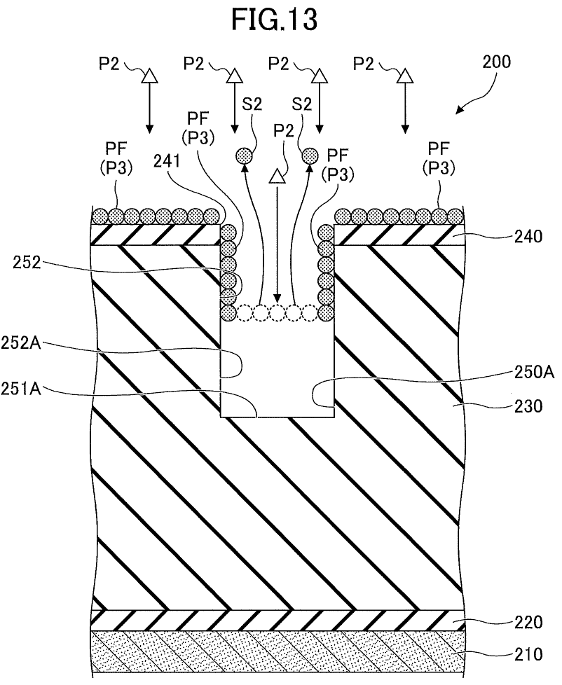

In the substrate processing method in the present disclosure, accordingly, by supplying the first gas and the plasma P2 of the second gas at the same time, oxide P3 (PF) of the electron receptors P1 can be formed on the film to be etched 230 at the same time when the first gas is supplied. Accordingly, while sufficiently protecting the portion (side faces 252 of the recess 250) of the film to be etched 230 on which the oxide PF of the electron receptors P1 is formed from the plasma, plasma etching can be applied to the film to be etched 230 (FIGS. 13 to 15).

Note that although the oxide PF of the electron receptors P1 is formed on the bottom face 251 of the recess 250 and the mask film 240, when the plasma etching is applied later to the film to be etched 230, the oxide PF is removed as sputters S2 by the supplied plasma (e.g., the plasma P2 of the second gas). Therefore, in the present disclosure, accumulation of the oxide PF of the electron receptors P1 around the opening 141 of the mask film 140 can be suppressed, and thereby, the opening 141 of the mask film 140 can be prevented from being blocked (see FIGS. 3 to 8).

### <Substrate Processing Apparatus>

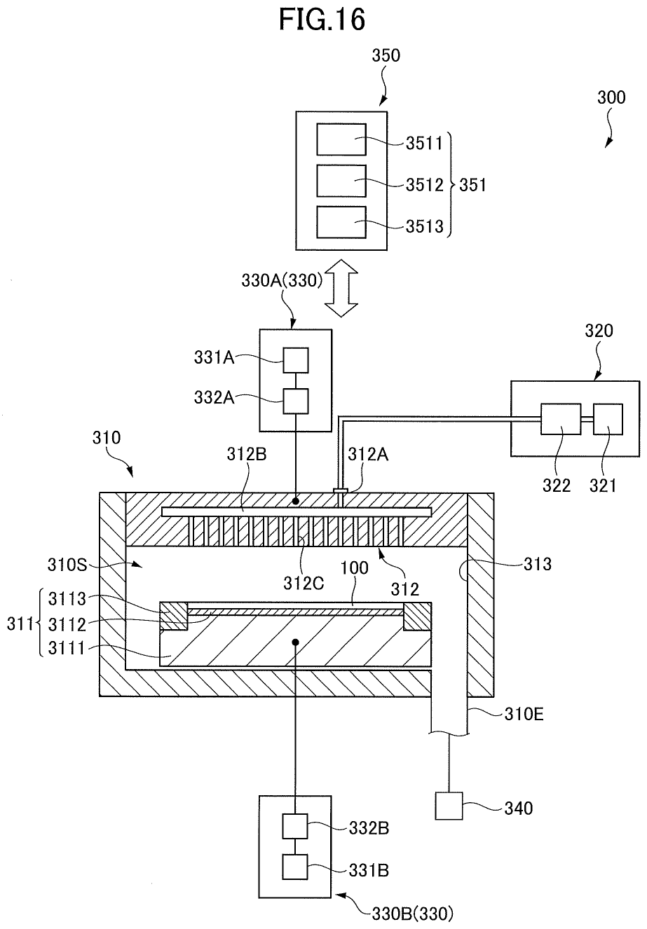

A substrate processing apparatus according to an embodiment will be described by using FIG. 16. FIG. 16 is a cross sectional schematic diagram illustrating an example of a substrate processing apparatus according to the present disclosure. Here, as an example of a substrate processing apparatus 300, a plasma processing device (e.g., a plasma etching device) will be described.

The substrate processing apparatus in the present disclosure has a chamber in which etching is applied to a substrate; and a controller, wherein the substrate has a film to be etched and a mask film covering the film to be etched, wherein the mask film has an opening to expose part of the film to be etched, and wherein the controller is configured to provide the substrate in the chamber; supply a first gas containing electron receptors to the film to be etched, through the opening; supply plasma of a second gas containing oxygen to the film to be etched; and execute controlling so as to apply plasma etching to the film to be etched.

Specifically, the substrate processing apparatus in the present disclosure is constituted with the substrate processing apparatus 300 that includes a chamber 310, a gas supply 320, an RF power supply 330, an exhaust system 340, and a controller 350.

The chamber 310 includes a support 311 and an upper electrode showerhead 312 in a processing space 310S, to apply etching to a substrate. The support 311 is disposed in a lower region of the processing space 310S in the chamber 310. The upper electrode showerhead 312 is disposed above the support 311, and can function as the ceiling part of the chamber 310. Note that the chamber 310 is an example of a chamber in which etching is applied to a substrate in the configuration of the substrate processing apparatus in the present disclosure.

The support 311 is configured to support the substrate in the processing space 310S. In the present disclosure, as the substrate, a circuit substrate 100 as described above is used (FIGS. 2, 3, and 16).

In the present disclosure, the support 311 includes a lower electrode 3111, an electrostatic chuck 3112, and an edge ring 3113. The lower electrode 3111 is supplied with RF power as will be described later. The electrostatic chuck 3112 is disposed on the lower electrode 3111, and is configured to support the circuit substrate 100 on the top surface of the electrostatic chuck 3112. The edge ring 3113 is disposed so as to surround the circuit substrate 100 along the periphery of the lower electrode 3111 on the top surface.

Note that the support 311 may include a temperature control module (not illustrated) configured to adjust at least one of the electrostatic chuck 3112 and the circuit substrate 100 to a target temperature. The temperature control module may include a heater, a flow channel, or a combination of these. A temperature control fluid such as a refrigerant or heat transfer gas flows through the flow channel.

The upper electrode showerhead 312 is configured to supply a processing gas from the gas supply 320 into the processing space 310S. The upper electrode showerhead 312 includes a gas inlet 312A, a gas diffusion chamber 312B, and multiple gas outlets 312C.

The gas inlet 312A communicates with the gas supply 320 and the gas diffusion chamber 312B. The multiple gas outlets 312C communicate with the gas diffusion chamber 312B and the processing space 310S. In the present disclosure, the upper electrode showerhead 312 is configured to supply the processing gas from the gas inlet 312A into the processing space 310S via the gas diffusion chamber 312B and the multiple gas outlets 312C.

The gas supply 320 may include a gas source 321 and a flow rate controller 322. In the present disclosure, the gas supply 320 is configured to supply the processing gas to the gas inlet 312A from the gas source 321 via the flow rate controller 322. The flow rate controller 322 may include, for example, a mass flow controller or a pressure control flow rate controller. The gas supply 320 may further include a flow rate modulation device that modulates or pulses the flow rate of the processing gas.

In the present disclosure, as the processing gas supplied to the processing space 310S of the chamber 310 by the gas supply 320, the first gas containing electron receptors P1 (boron trichloride) and the second gas P2 containing oxygen described above are used (FIGS. 5 and 6).

Note that when the first gas is supplied to the processing space 310S, an inert gas (such as argon) as a carrier gas of the first gas is mixed with the first gas, and supplied to the processing space 310S (FIGS. 4 and 16).

Also, after the first gas has been supplied to the processing space 310S, before supplying the plasma P2 of the second gas to the circuit substrate 100, the supply of the first gas containing the electron receptors P1 is stopped, the inert gas (such as argon) is supplied to the processing space 310S as the purge gas to purge the surface of the circuit substrate 100 (Step S23 in FIG. 10).

Further, when the plasma of the second gas is supplied to the circuit substrate 100, the inert gas (such as argon) is supplied to the processing space 310S as a single source gas to generate plasma (plasma ions) (Step S13 in FIG. 1 and Step S24 in FIG. 10).

The RF power supply 330 is configured to supply RF (Radio Frequency) power, for example, one or more RF signals, to the lower electrode 3111, the upper electrode showerhead 312, or both of the lower electrode 3111 and the upper electrode showerhead 312. Here, RF power stands for Radio Frequency power.

Accordingly, plasma is generated from the processing gas (the second gas and the inert gas) supplied to the processing space 310S. Therefore, the RF power supply 330 can function as at least part of the plasma generator that is configured to generate plasma from the processing gas (the second gas and the inert gas) in the chamber 310. In the present disclosure, the RF power supply 330 includes a first RF power supply 330A and a second RF power supply 330B.

The first RF power supply 330A includes a first RF generator 331A and a first matching circuit 332A. In the present disclosure, the first RF power supply 330A is configured to supply a first RF signal to the upper electrode showerhead 312 from the first RF generator 331A through the first matching circuit 332A. For example, the first RF signal may have a frequency within a range of 27 MHz to 100 MHz.

The second RF power supply 330B includes a second RF generator 331B and a second matching circuit 332B. In the present disclosure, the second RF power supply 330B is configured to supply a second RF signal to the lower electrode 3111 from the second RF generator 331B through the second matching circuit 332B. For example, the second RF signal may have a frequency within a range of 400 kHz to 13.56 MHz. Note that in the second RF power supply 330B, a DC (Direct Current) pulse generator may be used instead of the second RF generator 331B.

Note that in the present disclosure, other embodiments that are not illustrated may be adopted. For example, the RF power supply 330 may be configured to supply the first RF signal from an RF generator to the lower electrode 3111, and supply the second RF signal from another RF generator to the lower electrode 3111. Also, the RF power supply 330 may be configured to supply the first RF signal from an RF generator to the lower electrode 3111, supply the second RF signal from another RF generator to the lower electrode 3111, and further supply a 3th RF signal from yet another RF generator to the upper electrode showerhead 312. Further, the RF power supply 330 may be configured to apply a DC voltage to the upper electrode showerhead 312.

Also, in various embodiments, the amplitude of one or more RF signals (e.g., the first RF signal, the second RF signal, etc.) may be pulsed or modulated. The amplitude modulation may include pulsing the RF signal amplitude between an on state and an off state, or between two or more different on states.

The exhaust system 340 is connected to an exhaust port 310E that is provided, for example, in the bottom face of the chamber 310. The exhaust system 340 may include a pressure valve and a vacuum pump. The vacuum pump may be a turbomolecular pump, a roughening vacuum pump, or a combination of these.

The controller 350 processes computer-executable instructions that causes the substrate processing apparatus 300 to execute the substrate processing method described above in the present disclosure. The controller 350 is configured to control the respective elements of the substrate processing apparatus 300. In the present disclosure, although the entirety of the controller 350 is configured as part of the substrate processing apparatus 300, the configuration is not limited as such; part of the controller 350 may be configured as part of the substrate processing apparatus 300, or part of or the entirety of the controller 350 may be provided separately from the substrate processing apparatus 300.

The controller 350 may include, for example, a computer 351. The computer 351 may include, for example, a processor 3511, a storage unit 3512, and a communication interface 3513. Note that the controller 350 is an example of a controller that constitutes part of the substrate processing apparatus according to the present disclosure.

The processor 3511 is, for example, a CPU (Central Processing Unit), and can be configured to execute various control operations based on a program stored in the storage unit 3512. The storage unit 3512 may include a RAM (Random Access Memory), a ROM (Read-Only Memory), an HDD (Hard Disk Drive), an SSD (Solid State Drive), or a combination of these. The communication interface 513 may communicate with each element of the substrate processing apparatus 300 via a communication line such as a LAN (Local Area Network).

In the present disclosure, the chamber 310 is controlled by the controller 350, and Step S11, Step S21, and Step S31 described above are executed (FIGS. 1, 10, and 11).

Also, the gas supply 320 and the exhaust system 340 are controlled by the controller 350, and Step S12, Step S22, and Step S32 described above are executed (FIGS. 1, 10, and 11).

Further, the gas supply 320 and the RF power supply 330 are controlled by the controller 350, and Step S13, Step S23, Step S24, and Step S32 described above are executed (FIGS. 1, 10, and 11).

The substrate processing apparatus in the present disclosure has a stage that is provided in the chamber, on which the substrate is placed, and in the case where plasma etching is applied to the film to be etched, the controller executes controlling so as to supply RF power to the stage. Specifically, the RF power supply 330 is controlled by the controller 350, and the RF power is supplied to the support 311 provided in the chamber 310, on which the circuit substrate 100 is placed (FIG. 16). Note that the support 311 is an example of a stage that constitutes part of the substrate processing apparatus according to the present disclosure.

Accordingly, plasma (ions) of the second gas (gas containing oxygen) supplied as the processing gas to the processing space 310S is generated, and Step S13, Step S14, Step S15, Step S24, Step S25, Step S26, Step S32, Step S33, and Step S34 described above are executed (FIGS. 1, 10, and 11).

In the substrate processing apparatus 300 in the present disclosure, under control of the controller 350, into the chamber 310 in which etching is applied to the substrate, by supplying the first gas containing the electron receptors P1 to the film to be etched 130 through the opening 141 of the mask film 140, the electron receptors P1 can be adsorbed on part of the film to be etched 130 (recess 150) as a precursor to form a protection film. Also, by supplying the plasma P2 of the second gas containing oxygen to the film to be etched 130 after the first gas has been supplied, among the electron receptors P1 adsorbed on the film to be etched 130, some of the electron receptors P1 adsorbed onto the side faces 152 of the recess 150 react with oxygen radicals in the plasma P2 of the second gas, form the oxide PF, and the other electron receptors P1 adsorbed onto the bottom face 151 of the recess 150 and the mask film 140 are removed as the sputters S1 (see FIGS. 1 to 5).

Further, by applying plasma etching to the film to be etched 130, the oxide PF of the electron receptors P1 famed on the film to be etched 130 can protect a portion of the film to be etched 130 at which the oxide PF is famed from the plasma (the side faces 152 of the recess 150). Also, a portion of the film to be etched 130 (the bottom face 151 of the recess 150) at which the electron receptors P1 has been removed are exposed to the plasma. In this way, on the film to be etched 130 of the substrate, the portion at which the oxide PF of the electron receptors P1 is formed (the side faces 152 of the recess 150) is not etched, and only the portion at which the oxide PF is not famed (the bottom face 151 of the recess 150) is etched (see FIG. 5).

Also, as the etching advances, the recess 150A is further formed in the film to be etched 130 through the opening 141 of the mask film 140, and the first gas is adsorbed also on the bottom face 151A and the side faces 152A of the recess 150A. The electron receptors P1 adsorbed on the bottom face 151A of the recess 150A is removed as the sputters S1 by the plasma P2 of the second gas supplied subsequently, whereas the electron receptors P1 adsorbed on the side faces 152A of the recess 150B react with the plasma P2 of the second gas while being adsorbed on the side faces 152A, and the oxide PF (protection film) of the electron receptors P1 is formed on the side faces 152A of the recess 150B (see FIGS. 5 to 8).

Once plasma for etching including the plasma P2 of the second gas is supplied here, inside the recess 150 formed in the film to be etched 130, the bottom face 151B of the recess 150B is etched in a state where the side faces 152A of the recess 150B are protected by the oxide (protection film) PF of the electron receptors P1, and a through hole H such as the recess 150C is formed (see FIGS. 5 to 8). Therefore, according to the substrate processing apparatus 300 in the present disclosure, etching defects such as bowing can be suppressed

Also, although the first gas is also adsorbed on the mask film 140 containing the surroundings of the opening 141, the electron receptors P1 adsorbed on the mask film 140 is removed as the sputters S1 by the plasma P2 of the second gas; therefore, the oxide PF of the electron receptors P1 is not likely to be formed on the mask film 140. Therefore, according to the substrate processing apparatus 300 in the present disclosure, the oxide PF of the electron receptors P1 is not likely to be accumulated around the opening 141 of the mask film 140, the opening 141 of the mask film 140 can be prevented from being blocked (see FIGS. 5 to 8).

In the substrate processing apparatus 300 in the present embodiment, by causing the controller 350 to execute controlling so as to supply the RF power to the stage (the support 311) provided in the chamber 310 for placing the substrate (the circuit substrate 100), the stage (the support 311) to which the RF power is supplied can constitute a biased electrode. Accordingly, apart from ions of oxygen generated by the plasma P2 of the second gas or the plasma P2 of the second gas, etching plasma is drawn onto the surface of the substrate placed on the stage (the support 311), and thereby, the film to be etched 130 is etched. Accordingly, the etching of the film to be etched 130 is advanced to efficiently execute the etching process.

Also, in the substrate processing apparatus 300 in the present embodiment, the RF power is not supplied to a portion (e.g., sidewalls 313 in the chamber 310) other than the stage (the support 311) in the chamber 310; therefore, in the chamber 310, a portion other than the substrate placed on the stage (the support 311) are not easily etched. Therefore, erosion inside the chamber 310 and accompanying particle generation can be suppressed. Accordingly, the etching process can be executed stably and the maintenance of the substrate processing apparatus 300 becomes easier.

### Application Examples

In the following, the embodiments in the present disclosure will be described using application examples. Testing and evaluation of application examples and comparative examples were performed as follows.

### [Test Specimen (Substrate)]

As a test specimen, a circuit substrate 100 on which a wafer 110, an underlayer film (an inorganic insulating film) 120, a film to be etched 130, and a mask film 140 are layered in this order, was used. The wafer 110 was formed of silicon (Si); the inorganic insulating film 120 was constituted with alternately layered silicon nitride (SiN) and silicon oxide (SiO₂); the film to be etched 130 was formed of an amorphous carbon film (ACL); and the mask film 140 was formed of silicon oxynitride (SiON). The mask film 140 had an opening 141 formed to expose a portion of the film to be etched 130; the recess 150 was formed at a portion of the film to be etched 130 exposed to the opening 141; and a bottom face 151 and side faces 152 were formed in the recess 150 (see FIG. 3).

### [Etching]

Plasma etching was applied to the substrate (test specimen) by using the substrate processing apparatus 300 illustrated in FIG. 16.

### [Bowing]

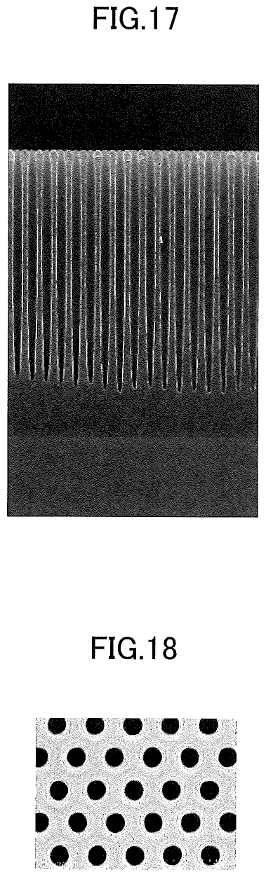

The maximum width (nm) of bowing was measured from an SEM image capturing a cross section of the substrate (test specimen) after etching (see FIGS. 17, 19, 21, and 23). Bowing was evaluated as good in the case of the maximum width (nm) of bowing being less than or equal to 120 nm, or as defective in the case of exceeding 120 nm.

### [Hole Blockage]

The opening of the substrate (test specimen) after etching was captured in an SEM image, to confirm the deposit (blocked state) around the opening (see FIGS. 18, 20, 22, and 24). Hole blockage was evaluated according to the following criteria, where 2 or greater was classified as good, and less than 2 was classified as defective.

3: No deposit was confirmed.
2: A little amount of deposit was confirmed, but blockage of the opening was not confirmed.
1: Blockage of the opening was confirmed.

### Application Example 1

A gas containing electron receptors not in a state of plasma as the first gas was supplied to the opening of the substrate (test specimen); thereafter, an inert gas (Argon gas) as the purge gas was supplied; thereafter, plasma of a mixed gas of oxygen (O₂) and carbonyl sulfide (COS) as plasma of the second gas was supplied; and thereafter, the plasma of the second gas was supplied as it was as the etching gas, to apply plasma etching, and the bowing and the hole blockage were evaluated (see FIGS. 17 and 18). Note that as the electron receptors in the first gas, a Lewis acid compound (boron trichloride (BCl₃)) was used. With respect to Application example 1, conditions of etching and results are tabulated in Table 1.

### Application Example 2

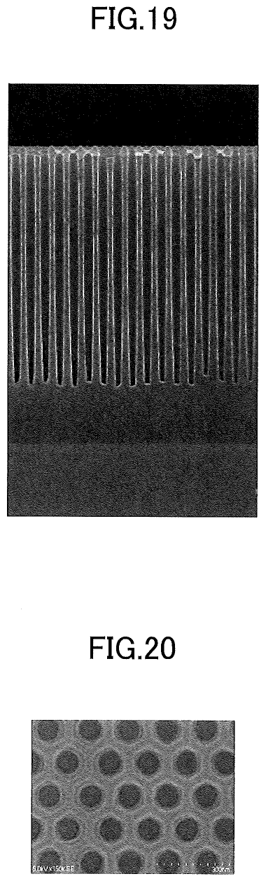

Plasma etching was executed and evaluated in substantially the same way as in Application example 1 except that the gas containing electron receptors as the first gas and the plasma of the gas containing oxygen (O₂) gas as the plasma of the second gas were supplied at the same time, and thereafter, the plasma of the mixed gas of oxygen (O₂) and carbonyl sulfide (COS) was supplied as the etching gas (see FIGS. 19 and 20). Conditions of etching and results are tabulated in Table 1.

### Reference Example 1

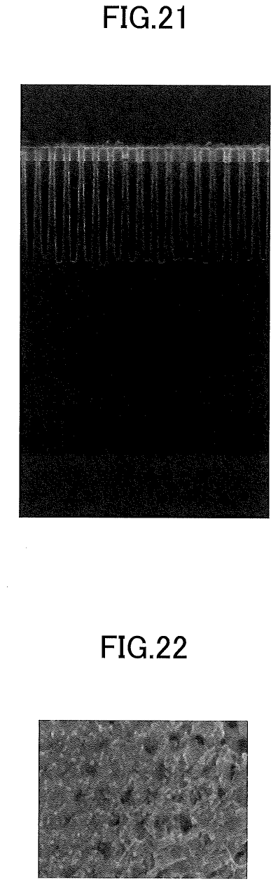

Plasma etching was executed and evaluated in substantially the same way as in Application example 1 except that neither the first gas nor the plasma of the second gas was supplied, and a gas containing boron trichloride (BCl₃) and the plasma of the mixed gas of oxygen (O₂) and carbonyl sulfide (COS) were supplied as the etching gas (see FIGS. 21 and 22). Conditions of etching and results are tabulated in Table 1.

### Comparative Example 1

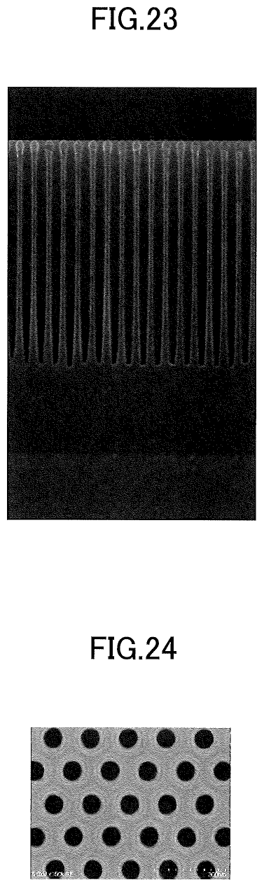

Plasma etching was executed and evaluated in substantially the same way as in Application example 1 except that neither the first gas nor the plasma of the second gas was supplied, and the plasma of the mixed gas of oxygen (O₂) and carbonyl sulfide (COS) was supplied as the etching gas (see FIGS. 23 and 24). Conditions of etching and results are tabulated in Table 1.

TABLE 1

| | Ex. 1 | Ex. 2 | Ref. ex. 1 | Comp. ex. 1 |
|---|---|---|---|---|
| First gas | BCl₃ (No | BCl₃/Plasma | — | — |
| | plasma) | | | |
| Plasma of | O₂/COS/ | O₂/Plasma | — | — |
| second gas | Plasma | | | |
| Etching | O₂/COS/ | O₂/COS/ | BCl₃/O₂/ | O₂/COS/ |
| | Plasma | Plasma | COS/Plasma | Plasma |
| Bowing (nm) | 109.7 | 110.3 | 109.3 | 126.8 |
| Hole blockage | 3 | 2 | 1 | 3 |

From Table 1, the substrates to which plasma etching was applied by supplying the gas containing electron receptors as the first gas, and the plasma of the gas containing oxygen gas as the plasma of the second gas at the same time, exhibited good evaluation results in both bowing and hole blockage.

In contrast, the substrates to which plasma etching was applied without supplying either the first gas or the second gas, exhibited defective evaluation results in bowing or in hole blockage.

From these results, by supplying the first gas containing electron receptor to a film to be etched through opening, supplying the plasma of the second gas containing oxygen to a film to be etched, and applying plasma etching to the film to be etched, it was understood that etching defects were suppressed.

As described above, according to one aspect in the present disclosure, a substrate processing method that suppresses etching defects can be provided.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A substrate processing method of etching a substrate that has a film to be etched and a mask film covering the film to be etched, wherein the mask film has an opening to expose part of the film to be etched, the substrate processing method comprising:
A) supplying a first gas containing electron receptors to the film to be etched, through the opening;
B) supplying plasma of a second gas containing oxygen to the film to be etched; and
C) applying plasma etching to the film to be etched.

2. The substrate processing method as claimed in claim 1, wherein the electron receptors are of a Lewis acid compound.

3. The substrate processing method as claimed in claim 1, wherein the electron receptors are of a boron containing compound.

4. The substrate processing method as claimed in claim 1, wherein the film to be etched has a recess formed through the opening.

5. The substrate processing method as claimed in claim 3, wherein the film to be etched has a recess formed through the opening.

6. The substrate processing method as claimed in claim 1, wherein plasma is not generated in said A).

7. The substrate processing method as claimed in claim 5, wherein plasma is not generated in said A).

8. The substrate processing method as claimed in claim 1, further comprising:
purging a surface of the substrate between said A) and said B).

9. The substrate processing method as claimed in claim 7, further comprising:
purging a surface of the substrate between said A) and said B).

10. The substrate processing method as claimed in claim 1, wherein said B) and said C) are executed at the same time.

11. The substrate processing method as claimed in claim 9, wherein said B) and said C) are executed at the same time.

12. The substrate processing method as claimed in claim 1, wherein said A) and said B) are executed at the same time.

13. The substrate processing method as claimed in claim 11, wherein said A) and said B) are executed at the same time.

14. The substrate processing method as claimed in claim 1, wherein said A), said B), and said C) are repeated.

15. The substrate processing method as claimed in claim 13, wherein said A), said B), and said C) are repeated.

16. A substrate processing apparatus comprising:
a chamber in which etching is applied to a substrate; and
a controller,
wherein the substrate has a film to be etched and a mask film covering the film to be etched,
wherein the mask film has an opening to expose part of the film to be etched, and
wherein the controller is configured to
provide the substrate in the chamber,
supply a first gas containing electron receptors to the film to be etched, through the opening,
supply plasma of a second gas containing oxygen to the film to be etched,
execute controlling so as to apply plasma etching to the film to be etched.

17. The substrate processing apparatus as claimed in claim 16, further comprising:
a stage provided in the chamber, on which the substrate is placed,
wherein in a case of applying the plasma etching to the film to be etched, the controller executes the controlling so as to supply RF power to the stage.
